(19) United States
(12) Patent Application Publication
(10) Pub. No.: US 2002/0137329 A1
(43) Pub. Date: Sep. 26, 2002

(54) Method for fabricating a barrier layer

(76) Inventors: Edberg Fang, Yuanlin Hsien (TW); Wen-Yi Hsieh, Hsinchu (TW); Tri-Rung Yew, Hsinchu Hsien (TW)

Correspondence Address: J.C. Patents, Suite 250, 4 Venture, Irvine, CA, 92618, US

(21) Appl. No.: 10/154,219

(22) Filed: May 20, 2002

Related U.S. Application Data
(62) Division of application No. 09/704,106, filed on Nov. 1, 2000.

(51) Int. Cl. H01L 21/4763

(52) U.S. Cl. 438/627

(57) ABSTRACT

A method is directed to forming a barrier layer, particularly suitable for use in a copper fabrication process. A substrate is provided. A conductive structure layer may have already been formed on the substrate. An inter-metal dielectric layer is formed over the substrate. The inter-metal dielectric layer is then patterned to form an opening that exposes the substrate. An oxygen getter layer is formed over the inter-metal dielectric layer and the opening. A barrier layer is formed on the oxygen getterlayer. A copper layer is deposited over the barrier layer. An oxidation of the oxygen getter layer is occurred in the subsequent high temperature steps. An oxide layer, serving as another barrier layer, is formed thereon. The oxygen getter layer includes any metal which can easily react with oxygen, such as titanium or tantalum.

### BACKGROUND OF THE INVENTION

1. Field of Invention

The present invention relates to semiconductor fabrication. More particularly, the present invention relates to a method for fabricating a barrier layer and the structure of the barrier layer.

2. Description of Related Art

As the integration of semiconductor device is greatly reduced down to a generation of 0.13 microns or less, it needs a high transmission speed in the logic circuit. In this kind of fabrication process, the dielectric material with high dielectric constant (high K) is no longer suitable for uses. Instead, a dielectric material with low dielectric constant (low K) is used in a damascene fabrication process, such as formation of copper interconnect structure. Here, the words of low K means those material having the dielectric constant less than 4.

FIG. 1A and FIG. 1B are cross-sectional drawings, schematically illustrating a conventional fabrication process to form a copper interconnect structure. In FIG. 1A, a substrate 100 is provided. On top of the substrate 100, a conductive structure layer 106 may have been formed thereon. An inter-metal dielectric layer 102 is formed over the substrate 100. The inter-metal dielectric layer 102 is patterned to form an opening 104 that exposes the conductive structure layer 106 of the substrate 100. Before the next process, the substrate 100 usually is subjected to a presputtering process for cleaning purpose.

In FIG. 1B, after cleaning of the presputtering process, a barrier layer 108 is formed over the inter-metal dielectric layer, and covering the peripheral surface of the opening 104. Then, an interconnect structure is accomplished. The formation of interconnect structure is well known by the one skilled in the art. The details are not further described here.

In the foregoing, when the presputtering process is performed to clean the surface of the low K dielectric layer 102, it naturally causes the low K dielectric layer 102 to be an oxygen-rich on its surface. In this manner, the invention foresees a problem that the oxygen atoms would diffuse into the barrier layer 108 and react with the barrier layer, resulting in a destruction on the barrier layer. The performance of the device is then affected.

### SUMMARY OF THE INVENTION

The invention provides a method for forming a barrier layer, particularly suitable for use in a copper fabrication process. Before forming a barrier layer on the inter-metal dielectric layer, a conductive oxygen getter layer is formed over the inter-metal dielectric layer. The oxygen getter layer can react with oxygen of the inter-metal dielectric layer, thereby an oxide layer is formed thereon. The oxide layer also serving as a barrier layer can prevent the oxygen of the inter-metal dielectric layer from entering into the barrier layer, causing destruction. The oxide layer can also prevent copper atoms from diffusing into the inter-metal dielectric layer, causing another kind of destruction on the inter-metal dielectric layer.

The invention provides a method for forming a barrier layer, particularly suitable for use in a copper fabrication process. The method includes providing a substrate. A conductive structure layer may have already been formed on the substrate. An inter-metal dielectric layer is formed over the substrate. The inter-metal dielectric layer is then patterned to form an opening that exposes the substrate. An oxygen getter layer is formed over the inter-metal dielectric layer and the opening. An oxidation occurs on the oxygen getter layer in the subsequent high temperature process, such as a temperature greater than 100° C., whereby an oxide layer, serving additional barrier function, is formed thereon. A second barrier layer is formed on the first barrier layer. A copper layer is deposited over the second barrier layer. In the foregoing, the inter-metal dielectric layer preferably includes an oxygen-rich dielectric layer. The oxygen getter layer includes any metal which can easily react with oxygen, such as titanium or tantalum.

The invention also provides a barrier structure in a copper fabrication process. The barrier structure includes a substrate. An inter-metal dielectric layer is located on the substrate, and has an opening exposing the substrate. A conformal metal oxide layer covers a surface of the inter-metal dielectric layer and the peripheral surface of the opening. The metal oxide layer is a first barrier layer. A conformal second barrier layer is located on the first barrier layer.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A and 1B are cross-sectional view, schematically illustrating a conventional method for forming a barrier layer in an interconnect structure; and

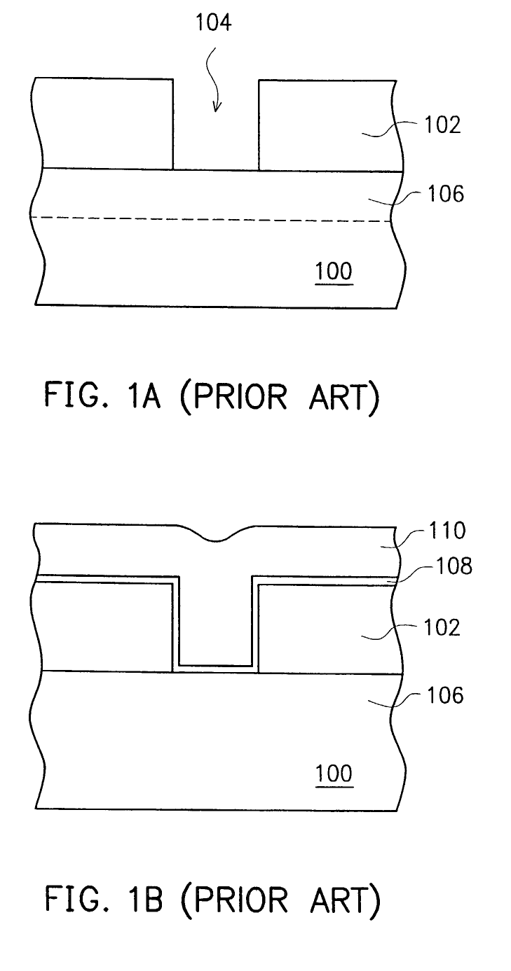

FIGS. 2A-2C are cross-sectional view, schematically illustrating a conventional method for forming a barrier layer in an interconnect structure, according to one preferred embodiment of this invention.

### DESCRIPTION OF THE PREFERRED EMBODIMENTS

While forming a damascene interconnect structure, a presputtering cleaning process usually causes the inter-metal dielectric layer to have high content of oxygen on its surface. The invention foresees that the oxygen atoms in the inter-metal dielectric layer may diffuse into the barrier layer that is subsequently formed, causing reaction. As a result, the function of the barrier layer is greatly degraded. Even further, the oxygen may also diffuses into the metal layer that is subsequently formed.

The invention suggests that an oxygen getter layer is formed before forming the barrier layer. The oxygen getter layer will react with the oxygen atoms existing in the inter-metal dielectric layer to form an oxide layer in the subsequent high temperature steps. The oxide layer can stop diffusing of oxygen atoms into the barrier layer or even into the interconnect structure, such as a copper interconnect, causing reaction. This causes destruction on the barrier layer and the interconnect structure. Moreover, the oxide layer also serves the barrier function, and thereby can prevent the metallic atoms of the interconnect structure, such as the copper atoms, from diffusing into the inter-metal dielectric layer. The oxide layer is a portion of the whole barrier structure layer.

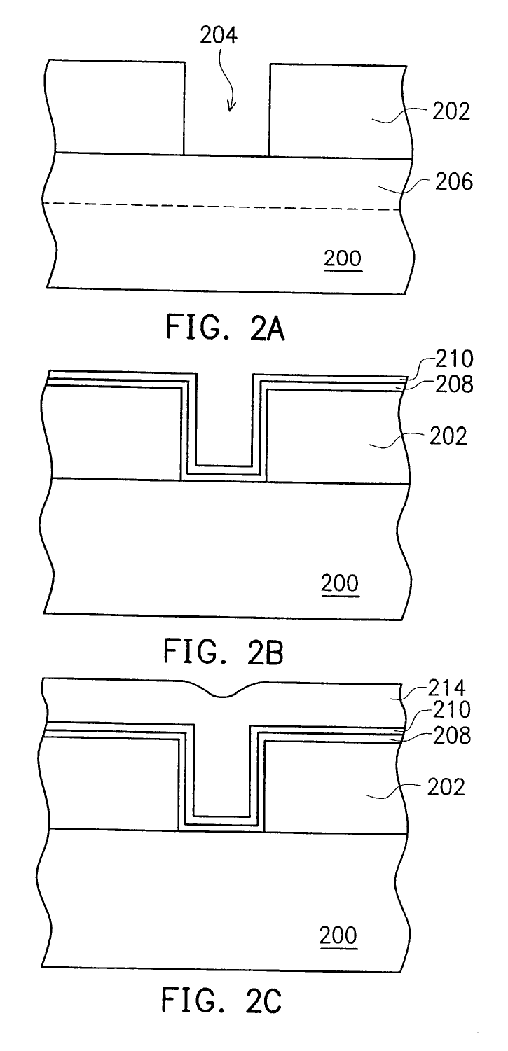

In the following, an example is provided for descriptions. FIGS. 2A-2C are cross-sectional view, schematically illustrating a conventional method for forming a barrier layer in an interconnect structure, according to one preferred embodiment of this invention. In FIG. 2A, a substrate 200 is first provided. On the substrate 200, it could have a conductive structure layer 206 already formed thereon. A dielectric layer 202 is formed over the substrate 200. The dielectric layer 202 includes, for example, a low K dielectric material, where K is less than 4. This inter-metal dielectric layer 202 is patterned to have an opening 204, which exposes the conductive structure layer 206 of the substrate 200. Before the next fabrication process, a presputtering process for cleaning purpose is usually performed. The presputtering process causes the surface of the dielectric layer 202 to be oxygen rich.

In FIG. 2B, an oxygen getter layer 208 is deposited over the substrate 200. The oxygen getter layer 208 is formed by, for example, chemical vapor deposition (CVD) or physical vapor deposition (PVD) with a thickness of about 50-500 angstroms. Further still, the oxygen getter layer 208 includes any material or metal, which can easily react with oxygen, such as titanium, tantalum, or refractory metal.

After the oxygen getter layer 208 is formed, a barrier layer 210 is formed over the oxygen getter layer 208. The barrier layer 210 can be a typical barrier layer including, for example, tantalum, tantalum nitride, tantalum/tantalum nitride, titanium, titanium nitride, or titanium/titanium nitride. The barrier layer usually can enhance the adhesion ability for the metal layer formed subsequently.

In FIG. 2C, a metal layer, such as a copper layer 214, is deposited over the barrier layer 210 and filling into the opening 204. The subsequent processes to accomplish the interconnect structure, such as chemical mechanical polishing (CMP) the copper layer 214, are well known by the prior artisans and not further described here.

In the foregoing, the oxide layer 208 can avoid the destruction on the barrier layer 210 and the copper layer 214 due to the reaction with the oxygen atoms diffused therein. In addition, the oxide layer 208 can also serve together with the barrier layer 210, thereby to prevent the copper atoms from diffusing into the dielectric layer 202. The oxide layer 208 is a part of the whole barrier layer.

Continuously, an oxidation of the oxygen getter layer 208 is occurred in the subsequent high temperature process, where the temperature is, for example, higher than 100° C. As a result, the oxygen getter layer 208 is converted into an oxide layer. If the oxygen getter layer 208 is a titanium layer, the oxide layer is a titanium oxide layer. The oxygen getter layer 208 is essential in the present invention because it can absorb oxygen atoms in the dielectric layer 202, avoiding the destruction on the barrier layer or even the interconnect structure. Moreover, the oxygen getter layer 208 after reaction can also serve as a part of the barrier layer.

In conclusion, several features have at least been achieved as follow:

1. The invention includes first forming the oxygen getter layer before the barrier layer is formed over the inter-metal dielectric layer. The oxygen getter layer is triggered to react with oxygen in the inter-metal dielectric layer to form an oxide layer in the subsequent high temperature steps with a temperature greater than 100° C. As a result, the oxygen in the inter-metal dielectric layer is prevented from diffusing into barrier layer or interconnect structure, causing the destruction.

2. In the invention, due to the formation of the oxide layer, it can also prevent the metallic atoms of the interconnect structure from diffusing into the inter-metal dielectric layer, reducing the isolation effect.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for forming a barrier layer, comprising:
providing a substrate;
forming a dielectric layer on the substrate;
patterning the dielectric layer to form an opening that exposes the substrate;
forming an oxygen getter layer over the substrate, covering a surface of the dielectric layer and a peripheral surface of the opening; and
forming a second barrier layer on the first barrier layer.

2. The method according to claim 1, wherein before the step of forming the oxygen getter layer over the substrate, the method comprises performing a presputterning cleaning process on the dielectric layer.

3. The method according to claim 1, wherein the step of forming the dielectric layer on the substrate comprises forming a dielectric layer with low dielectric constant.

4. The method according to claim 1, wherein the step of forming the oxygen getter layer comprises performing a physical vapor deposition process.

5. The method according to claim 1, wherein the step of forming the oxygen getter layer comprises performing a chemical vapor deposition process.

6. The method according to claim 1, wherein the step of forming the oxygen getter layer comprises forming a titanium layer.

7. The method according to claim 1, wherein the step of forming the oxygen getter layer comprises forming a tantalum layer.

8. The method according to claim 1, wherein the step of forming the oxygen getter layer comprises forming a material layer, which can react with oxygen.

9. The method according to claim 1, wherein the step of forming the second barrier layer on the first barrier layer comprises forming a layer including one material selected from the group consisting of tantalum, tantalum nitride, and tantalum/tantalum nitride.

10. The method according to claim 1, wherein in the step of forming the conformal oxygen getter layer, the oxygen getter layer has a thickness between about 50 angstroms and about 500 angstroms.

11. A barrier layer structure, comprising
a substrate;
a dielectric layer formed on the substrate, wherein the dielectric layer has an opening to expose the substrate;
an oxygen getter layer, covering over a surface of the dielectric layer and a peripheral surface of the opening; and
a barrier layer, formed on the oxygen getter layer.

12. The barrier layer structure according to claim 11, wherein the dielectric layer comprises a dielectric material which contains a relative high oxygen concentration.

13. The barrier layer structure according to claim 11, wherein the dielectric layer comprises a dielectric material with low dielectric constant.

14. The barrier layer structure according to claim 11, wherein the oxygen getter layer has a thickness of 50-500 angstroms.

15. The barrier layer structure according to claim 11, wherein the oxygen getter layer comprises titanium.

16. The barrier layer structure according to claim 11, wherein the oxygen getter layer comprises tantalum.

17. The barrier layer structure according to claim 11, wherein the oxygen getter layer comprises one selected from the group consisting of a tantalum layer, a tantalum nitride layer, and a tantalum/tantalum nitride layer.
